(19) United States
(12) Patent Application Publication
(10) Pub. No.: US 2021/0215149 A1
(43) Pub. Date: Jul. 15, 2021

(54) ELECTROACTIVE POLYMER TRANSDUCER PUMP

(71) Applicant: MOTHERSON INNOVATIONS COMPANY LIMITED, London (GB)

(72) Inventors: Reinhold Langbein, Stuttgart (DE); Rudi Artem, Stuttgart (DE); Wolfgang Krisch, Stuttgart (DE); Romeo Wieczorek, Stuttgart (DE)

(21) Appl. No.: 17/214,119

(22) Filed: Mar. 26, 2021

Related U.S. Application Data
(63) Continuation-in-part of application No. PCT/EP2019/086090, filed on Dec. 18, 2019.

(30) Foreign Application Priority Data
Dec. 18, 2018 (DE) 10 2018 132 598.3

(51) Int. Cl. F04B 43/02; H01L 41/047; H01L 41/053; H01L 41/083; H01L 41/193; H01L 41/277

(52) U.S. Cl. CPC F04B 43/02; H01L 41/0471; H01L 41/277; H01L 41/083; H01L 41/193; H01L 41/0533

(57) ABSTRACT

An electroactive polymer transducer device includes a housing, a base film, plate or wall within the housing, and at least one stack of layers deposited on the base film, plate or wall with at least one housing wall extending from the base film, wherein the at least one stack of layers includes an alternating sequence of one or more plastic electroactive material layers and electrically conductive layers on top of each other. A method of making an electroactive polymer transducer device is also described.

### CROSS REFERENCE TO RELATED APPLICATIONS

This application is a continuation-in-part of International Patent Application No. PCT/EP2019/086090, filed on Dec. 18, 2019, which claims the benefit of priority to German Patent Application No. 10 2018 132 598.3, filed on Dec. 18, 2018, each of which is hereby incorporated herein by reference in its entirety for all purposes.

### BACKGROUND

### 1. Field of the Invention

The present disclosure relates to an electroactive polymer transducer device to a vehicle component as well as a vehicle including such an electroactive polymer transducer device which may include a pump. A method to produce an electroactive polymer transducer device and a method to operate an electroactive polymer transducer device are also described.

### 2. Related Art

The statements in this section merely provide background information related to the present disclosure and may not constitute prior art.

Car interiors and cockpits have always been a favorite location for switches and all kinds of input/output (I/O) devices and human machine interfaces (HMI). In recent years, their design and placement have become important due to a number of reasons, in particular the following reasons: (a) the number of functions and systems to control has increased, (b) the demands for ergonomic switches have increased meaning aiming for switches to be reached, understood and operated easily, and (c) design requirements demand a good styling and at least partly invisible switch (hidden switch).

Traditionally the switches were electro-mechanical devices assembled separately in the interior and cockpit directly switching the electric load. Recently they have become connected to a microcontroller (via lines or bus systems) and control electronic switch systems.

In order to deeper embed the input devices in the structure of the dashboard, there is a need to do this while manufacturing the structure or the surface of the dashboard and avoid a later assembly process of a separate switch. As a presumption, such devices have to reliable compact devices being easily to produce.

As customers appreciate an appealing optic and a mechanical/haptic click of a switch device, with a haptic feedback being an important principle of good HMI designs. Thus, there is a need to design such devices in a way they can give feedback to users operating the switches in addition to esthetic design requirements.

Among the various sub-classes of electroactive polymers (EAP), dielectric elastomers (DE) are used in products due to their simple operation principle, industrial scale manufacturability and long lifetime. Mechanical sensors, actuators and/or energy generators, even within a single device, each comprise an electrical insulating layer of elastomer, sandwiched between two deformable layers of electrically conductive material providing two electrodes.

A dielectric polymer actuator known from US 2005/0200238 A1, comprises a laminate-type actuating part, comprising: at least one dielectric polymer film which has first and second surfaces positioned opposite to each other and a side surface interposed between the first and second surfaces and which includes an incompressible dielectric polymer; and first and second compliant electrodes connected to the first and second surfaces, respectively; and a frame formed along the side surface of the dielectric polymer film so that pre strain applied to the dielectric polymer film is about zero, wherein, when a voltage is applied through the first and second compliant electrodes to the dielectric polymer film, the laminate-type actuating part is warped in any one direction of first and second surface directions to provide displacement corresponding to the voltage applied.

Current lens and sensor cleaning technologies are electromagnetic and require user intervention to activate the cleaning system. The components to assemble a pump system for lens and sensor cleaning is sold in single components, such as nozzles, pumps and electronic parts, rather than entire systems. As a result they are often difficult to package and difficult to incorporate into current systems designs.

It is an object of the present invention to provide an electroactive polymer transducer device, in particular a compact and reliable input/output device, which is easy to produce.

### SUMMARY

In an aspect, an electroactive polymer transducer device includes at least one stack of multiple layers deposited on a base film, plate or wall within a housing with at least one housing wall, preferably extending from the base film. The stack includes an alternating sequence of plastic electroactive material layer(s) and electrically conductive layers on top of each other, with at least one plastic material layer, being sandwiched between two electrically conductive layers. Each plastic material layer includes at least one active area made of an elastic polymer providing an electrostrictive effect, with the active area being arranged laterally adjacent to at least one fixation area or at least one housing wall made of solid plastic material in direct contact to the active area, and the active area extending across the complete plastic material layer. The electrically conductive layers are arranged in an alternating sequence of first and second electrodes to apply a voltage between first and second electrodes to the respective active area(s) in order to induce or sense the electrostrictive effect of the elastic polymer of the plastic material layer arranged there between. The stack includes a cavity for a fluid to pass through, and wherein the stack of layers is prepared by three-dimensional printing technology or by layer-by-layer injection molding technology or by pressure casting.

In another aspect, a method of making an electroactive polymer transducer device includes the steps of providing a base film, plate or wall for a stack of multiple layers to be prepared on top of the base film, plate or wall or within a housing with at least one housing wall extending from the base wall. Then preparing the stack with at least one plastic material layer, which is sandwiched between two electrically conductive layers and including an elastic polymer providing an electrostrictive effect and a dielectric polymer, where the stack defines a cavity for fluid to flow through.

It should be noted that the features set out individually in the following description can be combined with each other in any technically advantageous manner and set out other forms of the present disclosure. The description further characterizes and specifies the present disclosure in particular in connection with the Figures.

### BRIEF DESCRIPTION OF THE DRAWINGS

In order that the disclosure may be well understood, there will now be described various forms thereof, given by way of example, reference being made to the accompanying drawings, in which:

FIG. 1 shows a schematic side view of a layer stack of a first electroactive polymer transducer device according to the present invention;

FIG. 2 shows a schematically top view onto stacked active areas of plastic material layers of the layer stack of FIG. 1;

FIG. 3 shows a schematically top view onto one embodiment of the layer sequence of first electrode/plastic material layer/second electrode;

FIG. 4 shows a schematically top view onto another embodiment of the layer sequence of first electrode/plastic material layer/second electrode;

FIG. 5 shows a method to produce the electroactive polymer transducer device according to the present invention;

FIG. 6 shows a method to produce the electroactive polymer transducer device according to the present invention;

FIG. 7 shows a method to operate the electroactive polymer transducer device according to the present invention;

FIG. 8 shows an exploded view of a layer stack for a second electroactive polymer transducer device according to the present invention;

FIG. 9 shows a method to produce the layer stack of FIG. 8;

FIGS. 10A and 10B each shows a cross sections of two alternatives of the second electroactive polymer transducer device;

FIGS. 11A and 11B each shows a cross sections of a third electroactive polymer transducer device according to the present invention;

FIGS. 12A and 12B show different multisensor areas including a layer stack according to FIG. 8 in each sensor area;

FIG. 13 shows a schematic side view of a layer stack of a first electroactive polymer transducer device with a pump according to the present invention;

FIG. 14 shows a schematically top view onto stacked active areas of plastic material layers of the layer stack of FIG. 13;

FIG. 15 shows a schematic side view of a layer stack of a two cylinder electroactive polymer transducer device with a pump and one joint pin with corresponding schematic top views of the stacked active areas of plastic material layers of the layer stack;

FIG. 16 shows a schematic top view of a layer stack of a four cylinder electroactive polymer transducer device with one joint pin;

FIG. 17 shows a schematic top view of a layer stack of a six cylinder electroactive polymer transducer device with one joint pin;

FIG. 18 shows a schematic top view of an electroactive polymer transducer device with a pump in combination with a muffler system.

### DETAILED DESCRIPTION

The following description is merely exemplary in nature and is not intended to limit the present disclosure, application, or uses. It should be understood that throughout the drawings, corresponding reference numerals indicate like or corresponding parts and features.

The object is solved by an electroactive polymer transducer device including at least one stack of multiple layers deposited on a base film, plate or wall and/or within a housing with at least one housing wall, preferably extending from the base wall, where the stack includes an alternating sequence of plastic material layers and electrically conductive layers on top of each other, with at least one plastic material layer, being sandwiched between two electrically conductive layers, wherein each plastic material layer includes at least one active area made of an elastic polymer providing an electrostrictive effect, with the active area being arranged laterally adjacent to at least one fixation area or at least one housing wall made of solid plastic material in direct contact to the active area, and/or the active area extending across the complete plastic material layer, wherein the electrically conductive layers are arranged in an alternating sequence of first and second electrodes to apply a voltage between first and second electrodes to the respective active area(s) in order to induce or sense the electrostrictive effect of the elastic polymer of the plastic material layer arranged there between, and wherein the stack of layers is prepared by three-dimensional printing technology or by layer-by-layer injection molding technology or by low or high pressure casting.

In one alternative, with the multiple layers being deposited on a base plate, the first electrode at least partly covers a first fixation area of the fixation area and the active area of the adjacent plastic material layers and the second electrode at least partly covers a second fixation area of the fixation area and the active area of the adjacent plastic material layers. In another alternative, with the multiple layers being deposited within a cavity defined by the at least one housing wall, preferably the at least one housing wall and the base wall of the housing, all layers are in contact with the at least one wall.

The elastic polymer might be any suitable polymer material showing the electrostrictive effect. Electrostriction is a property of electrical non-conductors, or dielectrics, which causes them to change their shape under the application of an electric field, and is caused by a slight displacement of ions in the crystal lattice upon being exposed to an external electric field. Positive ions will be displaced in the direction of the field, while negative ions will be displaced in the opposite direction. This displacement will accumulate throughout the bulk material and result in an overall strain (elongation) in the direction of the field. The thickness will be reduced in the orthogonal direction of a layer of such material characterized by Poisson's ratio. The area of the layer, where the electrostrictive effect occurs, is denoted as active area. The elastic polymer might be a di-electric elastic polymer, preferably a material with a high di-electric coefficient. The plastic material for the fixation areas might be any plastic material with significant lower elasticity as the material of the active area. In the active area, the material may have a hardness of 10 shore-A or more. In the fixation area the material may have a hardness of at least 60 shore-A, preferably of 20-90 shore-D. The hardness according to the shore scale measures the resistance of a sample to material deformation due to a constant compression load from a sharp object. The material for the electrically conductive layers might be any material providing a sufficient conductivity to apply a homogeneous voltage across the active area underneath or on top of the electrically conductive layer, e.g. a conductive ink applied during layer preparation.

Active and fixation areas of the plastic material layers of some embodiments are arranged laterally adjacent meaning that the corresponding areas of one layer are located beside each other in a direction parallel to the layer surface. In contrast to that, the electrode layers are arranged underneath and/or on top of each of the plastic material layer. The first and second fixation areas might be arranged on the same side of the device or might be arranged on the left and on the right of the active area, when considering a side view of the layer stack. On the same side denotes an arrangement, where the fixation areas are located either on the right or on the left side of the stack of layers. The first and second fixation areas may also embrace the active area in a circle fully or partly. In case of arranging the fixation areas on the same side of the active area, the resulting device can be manufactured with smaller lateral sizes enabling a placement of more corresponding devices in a given area.

In other embodiments the active area(s) can be embraced by one or more housing side walls.

Three-dimensional (3D) printing technology is an excellent solution for depositing many stable layers with good stacking accuracy. 3D Printing is based on a similar number of layers as required for manufacturing the electroactive polymer transducer device according to the present invention. 3D-printing and layer-by-layer injection molding are technologies suitable to provide a layer stack being flexible, e.g. in the middle where the active area(s) is/are arranged, which change its thicknesses due to applied voltage or applied external mechanical force, and being stable at the fixation areas to reliably apply an electrical contact to the electrodes. Alternative technologies such as ablation, milling, sputtering, evaporation, Rakel-printing or centrifugal layer deposition are not suitable to produce as huge amount of electroactive polymer transducer device as required in mass production. The non-suited technologies require a huge amount of time and effort for producing an electroactive polymer transducer device leading to non-acceptable production costs. 3D-Printing or layer-by-layer injection molding are very suited for mass production of the electroactive polymer transducer device according to the present invention. With these technologies it is possible embed the electroactive polymer transducer device as Input/output devices in the structure of the dashboard while manufacturing the structure or the surface of the dashboard avoiding a later assembly process of a separate electroactive polymer transducer device.

Casting can use RIM (reaction injection molding) technology, which differs from injection molding by using thermosetting polymers, with polyurethane being favored.

The resulting electroactive polymer transducer devices can be used as actuator devices and/or sensing devices such as switches. There is an opportunity to combine two devices according to the present invention in one arrangement and operate one of them as sensor or switch and the other one is an actuator and/or acoustic feedback device. In case of a combined sensor/actuator combination, the feedback mechanism can be programmed to mimic key-click characteristics of a mechanical switch over a wide range. Such specified characteristics, where for instance the resistance is high in the beginning and decreased after the click-point in common in the industry and is considered an excellent haptic feedback.

Therefore, the electroactive polymer transducer device provides a compact and reliable input/output device being easy to produce and being appreciated as a human machine interface by the users.

In another embodiment the stack of layers includes 10 to 50 sequences of plastic material layer and electrically conductive layer. The electrostrictive effect increases proportional to the number of layers including active material. The number of 10 to 50 layers provides an overall electrostrictive effect which can be used to significantly actuate a component and to sense a pressure applied to the stack of layers with improved accuracy.

In an embodiment, the first electrodes are connected in parallel to be connected to a first polarity of a power supply, while the second electrodes are connected in parallel to be connected to a second polarity of the power supply. The parallel connection of all first and all second electrodes enables to use one simple power supply to supply voltage to all electrodes, where the polarity alternates in a vertical direction through the layer stack in order to achieve a maximum electrostrictive effect.

In another embodiment, the first electrodes include first contacting areas at least partly covering the first fixation areas and the second electrodes include second contacting areas at least partly covering the second fixation areas, where when projected onto the base plate the first contacting areas at least do not fully cover the second contacting areas and vice versa. The first and second contacting areas can be used to connect the first and second electrodes to one or more power supplies. The at least partly non-overlapping first and second contacting areas and the resulting vertical coverage of the contacting areas for all first electrodes and separately also for all second electrodes enables to connect all first or all second electrodes together by just providing a vertical conductive path through all the corresponding first or second fixation areas of the layer stack.

In another embodiment, the parallel connection of the first electrodes and also of the second electrodes is established by at least two separate conductive pins or vias extending through the stack of layers, of which at least one extending through the first contacting areas and not the second contacting areas and of which at least one extending through the second contacting areas and not the first contacting areas. This electrical connection can simply be established by inserting a pin vertical to the surface of the stack of layers into the already prepared layer stack just penetrating all layers to connect all first or second electrodes without the need of layer structuring during layer preparation. The resulting step for electrically connecting the electrodes is very simple and non-expensive. For example, the pin or via may protrude from the layer stack and be connected to the power supply via conducting wires bonded to the protruding pin or via.

In another embodiment, the fixation area includes separate first and second fixation areas, where the active area of each plastic material layer is arranged laterally between first and second fixation areas in direct contact to the active area. This arrangement provides a resulting electroactive polymer transducer device being mechanically more stable compared to a device where the fixation areas are arranged only on one side of the layer stack, because the active layer is supported by solid plastic material on both sides, or even laterally on all sides.

In another embodiment, the electrically conductive layers have a smooth shape in a lateral direction without edges at least in the area covering the active areas of the plastic material layers. The shape in the lateral direction of a layer is the shape visible when looking on top of the layer in a vertical direction to the layer surface. This smooth lateral shape of the conductive layers avoids sharp edges eventually leading to non-desired peaks in voltage or current between adjacent electrodes and therefore prevents or suppresses electrical discharges within the stack of layers. This protects the functionality of the electroactive polymer transducer device and increases its lifetime. In a preferred embodiment, the electrically conductive layers are circular shaped layers when seen in a vertical direction to a surface of the conductive layers. As an example, the shape of the electrically conductive layers may consist of a circle covering the active area completed by two tangential lines touching each of the electrodes at just one point covering the first and second fixation areas, where the electrodes might be connected by a conductive pin.

In another embodiment, the size of the active area decreases from layer to layer starting with the biggest size for the plastic material layer on top of the base plate. This further increases the resistance against electric discharges because the distance between the electrode edges of one electrode and the next electrode underneath is increased. Additionally, the stack of layers becomes more elastic and stable. Here, the active areas might be arranged symmetrically to the active area underneath, where a center of the active areas coincide for all active areas. The active areas may also have a circular shape and might be arranged in a concentric way seen in a vertical direction to a surface of the active areas.

In another embodiment, the base plate is made of the solid plastic material also used to prepare the fixation areas. Using the same material as used for the fixation areas in the plastic material layers makes the production process more easily enabling to continue the layer deposition process without an interruption after having prepared the base plate. In another embodiment, 1 to 5 separate layers applied on top of each other establish the base plate. In case of using 3D printing the thickness of the base layer might be provided by printing 1 to 5 layers of the same material.

In an alternative embodiment, the base film includes a stretchable and/or deformable layer, in particular in form of a textile film.

In another embodiment, in the plastic material layer the first and second fixation areas laterally fully embrace the active area. Here, the first and second fixation areas give mechanical stability from all sides to the stack of layers, especially to the active area when changing its thickness due to application of voltage or external mechanical forces. It is also possible that the complete plastic material layer provides an active area.

In other embodiments, the layer stack includes a protective layer on at least one of its two opposite sides, and/or the layer stack is covered by a solid top cover or a slush skin and/or a décor layer on a side opposite to the base film, plate or wall. The cover can adapt the haptic feeling of the electroactive polymer transducer device by being touch by a user is case of applying the electroactive polymer transducer device as a sensor device. In addition, the cover can be provided with decor features.

The protective layer can be in the form of a paint; the slush skin can include polyurethane; and the décor layer can be provided as a leather layer. But it is also possible that two or all layers a provided together.

In another embodiment, the stack of layers and the base plate are prepared together, with preferably the base plate or wall and/or the protective layer and/or the electrode being arranged thereto being provided as combined component.

In another embodiment, the electroactive polymer transducer device is used as an actuator device and/or or as a sensor device further including a control unit connected to the electrically conductive layers. The electroactive polymer transducer device can be operated as an actuator, when applying a suitable voltage to decrease or increase the layer thickness of the active areas via the electrostrictive effect, where so-called electrostrictive forces squeeze the di-electric elastic polymer material of the active area. Typical voltages to be applied to the active area are between 100V and 2000V. With a sufficient number of plastic material layers within the layer stack, a change of thickness of about 10% can be achieve in order to actuate a component connected to the stack of layers. The device can also be used in a sensing mode, where a constant voltage might be applied by a power supply controlled by the control unit to the active areas of the electroactive polymer transducer device and sensing a change of an applied default voltage induced by pressing on top of the stack of layers, for example by a finger touching the top of the layer stack. The default voltage might by applied by a power supply via the control unit also analyzing the induced voltage change due to an applied pressure to the stack of layers. The sensed voltage change can be used as a trigger signal to initiate a certain response or any following action of another component. The control unit may trigger the following actions as a response on the sensed voltage change.

Embodiments can be further characterized in that the slush skin is provided with at least one actuation area, preferably in form of a button, in particular with a first portion projection from the slush skin away from the stack and/or with a second portion projection from the slush skin towards the stack.

The present disclosure further relates to a vehicle external or internal trim component, like a door trim or a dashboard, and to a vehicle including at least one of the electroactive polymer transducer devices according to the present disclosure used as an actuator device and/or or as a sensor device.

The present disclosure still further relates to a method of making an electroactive polymer transducer device, including the steps of: providing a base film, plate or wall for a stack of multiple layers to be prepared on top of the base film, plate or wall or within a housing with at least one housing wall, preferably extending from the base wall, and preparing the stack with at least one plastic material layer, which is sandwiched between two electrically conductive layers and including an elastic polymer providing an electrostrictive effect, preferably including a dielectric polymer, by three-dimensional printing technology or by layer-by-layer injection molding technology, or by casting technology.

It is possible that the stack is provided with a plurality of plastic material layers, wherein the plastic material layers each include an active area made of an elastic polymer providing an electrostrictive effect arranged laterally adjacent to at least one fixation area made of solid plastic material in direct contact to the active area, wherein the electrically conductive layers are arranged in an alternating sequence of first and second electrodes to apply a voltage between first and second electrodes to the active areas in order to induce or sense the electrostrictive effect of the elastic polymer, and wherein the first electrode at least partly covers a first fixation area of the fixation area and the active area of the adjacent plastic material layers and the second electrode at least partly covers a second fixation area of the fixation area and the active area of the adjacent plastic material layers.

Therefore, the method provides an electroactive polymer transducer device as a compact and reliable input/output device being easily to produce and being appreciated as human machine interface by the users.

In an embodiment of the method, also the base plate or wall is prepared by three-dimensional printing technology or by layer-by-layer injection molding technology.

Further embodiments may be characterized in that the housing is provided with a base wall and at last one wall defining a cavity into which the stack is inserted, and/or the housing is provided by injection molding technology. For these embodiments it is possible that the stack is inserted into the cavity via a carrier, preferably including the base film.

The present disclosure further relates to a method to operate an electroactive polymer transducer device as combined actuator and sensing device with good haptic feedback in a click operation as a switch, including the steps of applying a counter-voltage to electrically conductive layers, having a plastic material layer including dielectric material arranged there between, by a control unit in order to hamper a thickness-reduction of the active area of the plastic material layer(s) when beginning to apply an external mechanical force to the electroactive polymer transducer devices, preferably in the at least one actuation area, until a common click point is reached, and reversing the applied voltage by the control unit after the common click-point is passed to support the click operation.

A counter voltage denotes voltage applied to the first and second electrodes with a polarity suitable to prevent an electrostrictive effect. Therefore, the external pressure has to overcome a certain threshold to result in a decreased thickness of the stack of layers resulting in a change of voltage to be sensed. The felt mechanical resistance against the applied pressure is high in the beginning and decreases after the click-point, which provides an excellent haptic feedback to the user. The mechanical/haptic click of the resulting switch device is appreciated by customers and haptic feedback is an important principle of good HMI designs provided by the method of operation according to the present disclosure. This effect is difficult to achieve by the material properties of the plastic layers alone.

Thus, according to embodiments, dielectric elastomers are used as sensors. Said sensors can be provided in the form of a sensor film which can be integrated on or below a surface of a vehicle component. Such a sensor film can include a multisensor area in order to be used for different control approaches. A localized feedback arrangement can be provided by which a person can recognize the boundary of a virtual button and can also guide the finger blindly from one location to another on a surface without the need of a specific shape of said surface.

The foregoing description of various preferred embodiments has been presented for purposes of illustration and description. It is not intended to be exhaustive or to limit the disclosure to the precise forms disclosed, and many modifications and variations are possible in light of the above teaching. The example embodiments, as described above, were chosen and described in order to best explain the principles of the disclosure and its practical application to thereby enable others skilled in the art to best utilize the disclosure in various embodiments and with various modifications as are suited to the particular use contemplated.

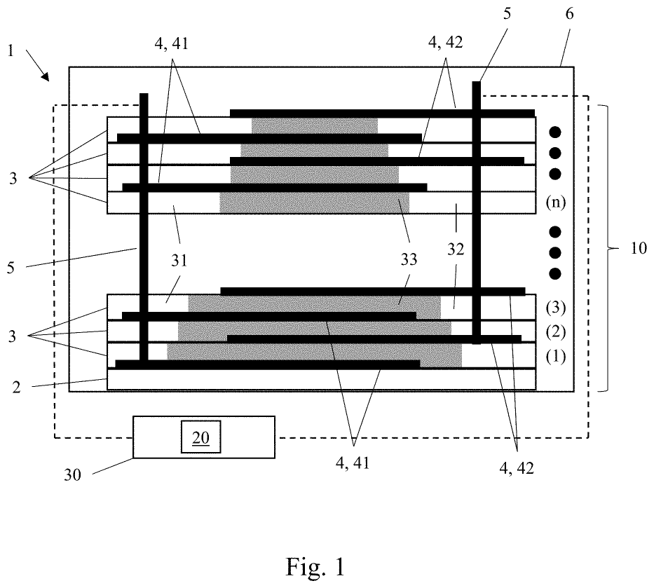

FIG. 1 shows a schematic side view of a layer stack 10 of a first electroactive polymer transducer device 1 according to the present disclosure. Said stack 10 of multiple layers is deposited on a base plate 2. The multiple more than n layers are indicated on the right side with numbers (1), (2), (3) . . . (n), . . . . The stack of layers may include 10 to 50 sequences of plastic material layer 3 and electrically conductive layer 4. The stack 10 includes an alternating sequence of plastic material layers 3 and electrically conductive layers 4 on top of each other. The plastic material layers 3 each include an active area 33 made of an elastic polymer providing an electrostrictive effect (gray shaded areas) arranged laterally adjacent beside a first and a second fixation area 31, 32 made of solid plastic material in direct contact to the active area 33. The electrically conductive layers 4 are arranged in an alternating sequence of first and second electrodes 41, 42 to apply a voltage between first and second electrodes 41, 42 to the active areas 33 in order to induce or sense the electrostrictive effect of the elastic polymer, where the first electrode 41 at least partly covers a first fixation area 31 of the fixation area and the active area 33 of the adjacent plastic material layers 3 and the second electrode 42 at least partly covers a second fixation area 32 of the fixation area and the active area 33 of the adjacent plastic material layers.

Here, a first electrode 41 is deposited on top of the base plate 2 followed by a plastic material layer 3 with a second electrode 42 deposited on top of the plastic material layer 3 followed by the next plastic material layer 3 on top of the second electrode 42 and so on until a second electrode layer 42 is deposited as the last layer of the stack of layers 10. The sequence of layers define a vertical direction of the stack 10 of layers perpendicular to the base plate 2, here the surface of the base plate 2, where the stack 10 is deposited on top. The lateral arrangement of areas 31, 32, 33 within one layer 3 denotes areas located beside each other in a direction parallel to the surface of the base plate 2, where the stack 10 is deposited on top.

The first electrodes 41 are connected in parallel to a first polarity of a power supply 20, while the second electrodes 42 are connected in parallel to a second polarity of the power supply 20 by separate conductive pins 5 extending through the stack of layers 10, the left one extending through the first contacting areas 411 and not the second contacting areas 421. And the right one extending through the second contacting areas 421 and not the first contacting areas 411. This simple contacting is enabled by first contacting areas 411 of the first electrodes 41 partly covering the first fixation areas 31 and the second electrodes 42 include second contacting areas 421 at least partly covering the second fixation areas 32, where when projected onto the base plate 2, the first contacting areas 411 do not cover or only partly cover the second contacting areas 421 and vice versa. Furthermore, the size of the active areas 33 decreases from layer to layer starting with the biggest size for the plastic material layer 3 on top of the base plate 2.

The base plate 2 might be made of the solid plastic material also used to prepare the fixation areas 31, 32, preferably, 1 to 5 separate layers applied on top of each other establish the base plate. In other embodiments, the base plate might be made of other non-conducting materials providing a sufficient flat and smooth (non-rough) surface suitable to deposit the stack of layers on top. The layer stack 10 might be covered by a solid top cover 6 on a side opposite to the base plate 2. The solid top cover 6 might be made of hard plastic, which can be fitted to the top of the assembly providing a desired haptic feeling.

The stack of layers 10, preferably also the base plate 2, might be prepared by three-dimensional printing technology or by layer-by-layer injection molding technology. The electroactive polymer transducer device 1 might be used as an actuator device and/or or as a sensor device further including a control unit 30 connected to the electrically conductive layers 4.

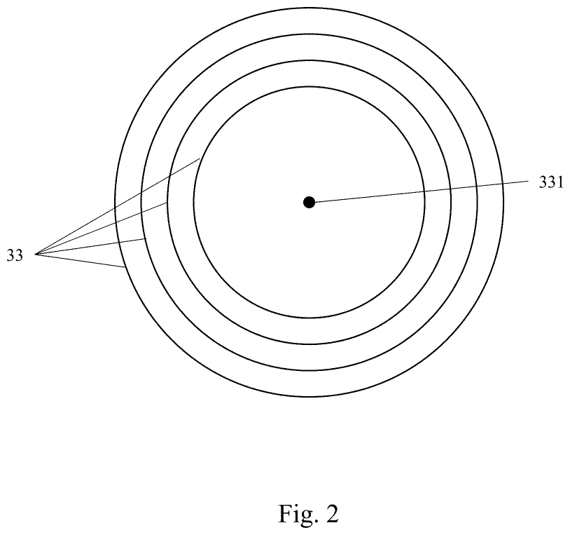

FIG. 2 shows a schematically top view onto the stacked active areas 33 of the plastic material layers 3. For a better overview, only the active areas 33 of the plastic material layers 3 are shown. Here the size of the active areas 33 decreases from layer to layer starting with the biggest size for the plastic material layer 3 on top of the base plate 2. The active areas 33 are arranged symmetrically to the active area 33 underneath, where a center 331 of the active areas 33 coincide for all active areas 33. The active areas 33 have a circular shape and are arranged in a concentric way seen in a vertical direction to a surface of the active areas 33.

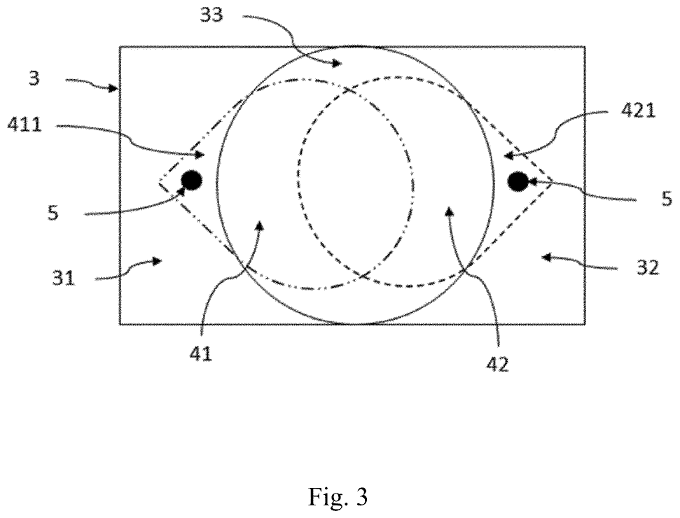

FIG. 3 shows a schematically top view onto one embodiment of the layer sequence of first electrode 41/plastic material layer 3/second electrode 42. In the plastic material layer 3 the first and second fixation areas 31, 32 laterally fully embrace the active area 33 in this embodiment. The shown layer structure corresponds to the stack of layers 10 shown in FIG. 1. Here the first and second electrodes 41, 42 have smooth circular shape in lateral direction without edges at least in the area covering the active areas of the plastic material layers 3 when seen in a vertical direction to a surface of the first and second electrodes 41, 42, where the shape of the electrodes 41, 42 is completed by tangential lines touching each of the electrodes 41, 42 in just one point. The areas of the electrodes 41, 42 outside the active area 33 (not covering the active area 33) are the first and second contacting areas 411, 421, where the vertical pin 5 is positioned.

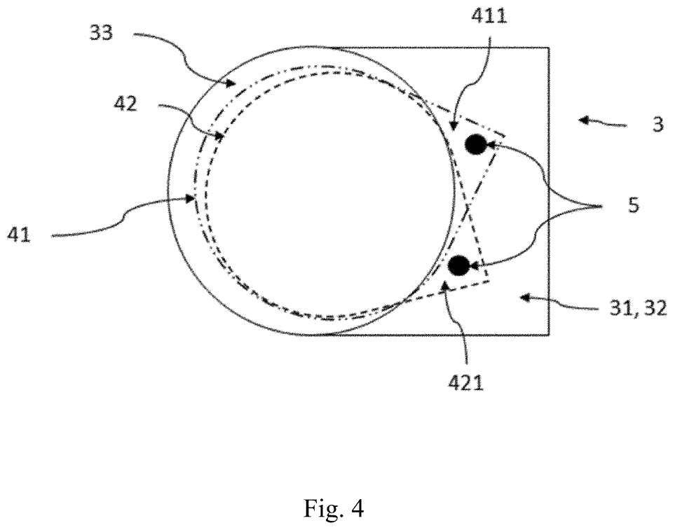

FIG. 4 shows a schematically top view onto another embodiment of the layer sequence of first electrode 41/plastic material layer 3/second electrode 42. Here the plastic material layer 3 include an active area 33 arranged laterally adjacent to the fixation area 31, 32 only provided on one side (right side) of the active area 33. Also here, the first and second electrodes 41, 42 have smooth circular shape in lateral direction without edges at least in the area covering the active areas 33 of the plastic material layers 3 when seen in a vertical direction to a surface of the first and second electrodes 41, 42, where the shape of the electrodes 41, 42 is completed by tangential lines touching each of the electrodes 41, 42 in just one point. The areas of the electrodes 41, 42 outside the active area 33 (not covering the active area 33) are the first and second contacting areas 411, 421, where the vertical pin 5 is positioned. The first and second contacting areas are slightly shifted against each other in order to essentially avoid coverage of one of the contacting surfaces 411 dedicated to one electrode 41 by the other contacting surface 421 dedicated to the other electrode 42. As can be seen from FIG. 4, the electroactive polymer transducer device 1 can be manufactured with smaller lateral sizes compared to the electroactive polymer transducer device 1 of FIG. 3. However, the mechanical stability of the active area and therefore of the whole electroactive polymer transducer device 1 of FIG. 3 is larger than for the electroactive polymer transducer device 1 of FIG. 4.

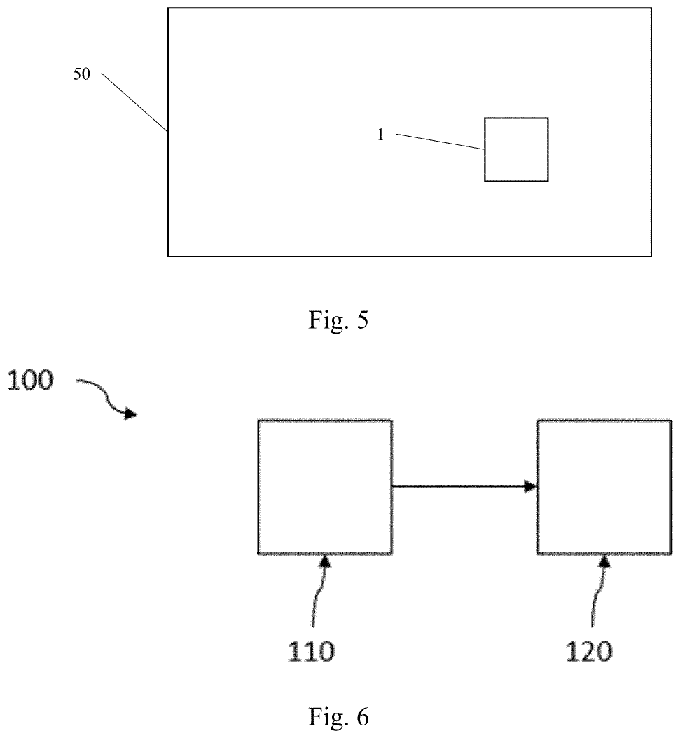

FIG. 5 shows an embodiment of a vehicle 50 including at least one electroactive polymer transducer device 1 according to the present disclosure used as an actuator device and/or or as a sensor device. The vehicle 50 might be a motorized or non-motorized vehicle. It might be a two-wheel, three-wheel, or four-wheel vehicle 50, or a vehicle 50 including more wheels. The vehicle 50 might be used to transport people and/or objects. The vehicle 50 might be driven by a driver or an autonomous driven vehicle. The vehicle 50 might include a door trim or a dashboard with an electroactive polymer transducer device 1.

FIG. 6 shows a method to produce the electroactive polymer transducer device 1 according to the present disclosure including the steps of providing 110 a base plate 2 for a stack 10 of multiple layer to be prepared on top of the base plate 2 and preparing 120 the stack 10 including an alternating sequence of plastic material layers 3 and electrically conductive layers 4 on top of each by three-dimensional printing technology or by layer-by-layer injection molding technology. The plastic material layers 3 may each include an active area 33 made of an elastic polymer providing an electrostrictive effect arranged laterally adjacent to at least one fixation area 31, 32 made of solid plastic material in direct contact to the active area 33. The electrically conductive layers 4 may be arranged in an alternating sequence of first and second electrodes 41, 42 to apply a voltage between first and second electrodes 41, 42 to the active areas 33 in order to induce or sense the electrostrictive effect of the elastic polymer. The first electrode 41 may at least partly cover a first fixation area 31 of the fixation area and the active area 33 of the adjacent plastic material layers 3, and the second electrode 42 may at least partly cover a second fixation area 32 of the fixation area and the active area 33 of the adjacent plastic material layers. Here also, the base plate 10 is prepared by three-dimensional printing technology or by layer-by-layer injection molding technology.

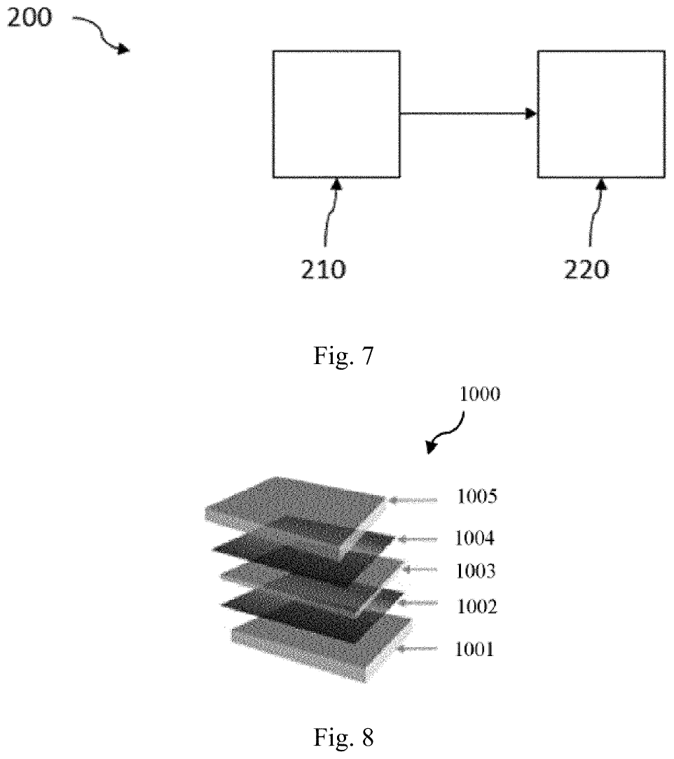

FIG. 7 shows a method to operate the electroactive polymer transducer device 1 according to the present disclosure as combined actuator and sensing device with good haptic feedback in a click operation as a switch. The method includes the steps of applying 210 a counter-voltage to the electrically conductive layers 4 by a control unit 30 in order to hamper a thickness-reduction of the active area 33 of the plastic material layers 3 when beginning to apply an external mechanical force to the electroactive polymer transducer devices 1 until a common click point is reached, and reversing 220 the applied voltage by the control unit 30 after the common click-point is passed to support the click operation.

FIG. 8 shows an exploded view of a layer stack 1000 for a second electroactive polymer transducer device according to the present disclosure. The layer stack 1000 includes, on top of each other, a protective layer 1001, an electrode layer 1002, a dielectric layer 1003, a further electrode layer 1004 and a further protective layer 1005, produced e.g. by injection molding. Using three-dimensional printing technology or layer-by-layer injection molding technology or low or high pressure casing allows serial production.

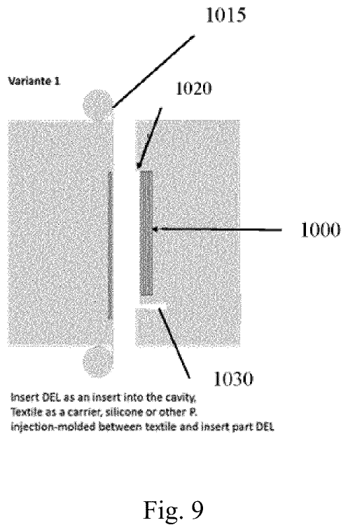

Said layer stack 1000 can be inserted into a cavity of a housing 1014 by providing the same on a thin carrier such as a textile film 1015 for transfer into the cavity by passing a gap 1020 as shown in FIG. 9. With the carrier, the layer stack 1000, is also preferably provided in form of a thin film, becoming more stable and more resistant, where the thickness of the film can be varied depending on the desired sensitivity of the electroactive polymer transducer device.

The cavity may be defined by a base wall 1014c and at least one housing wall 1014a, 1014b extending therefrom, as shown in FIG. 9 and described above. The housing 1014 can also be formed by injection molding as illustrated via an injection port 1030.

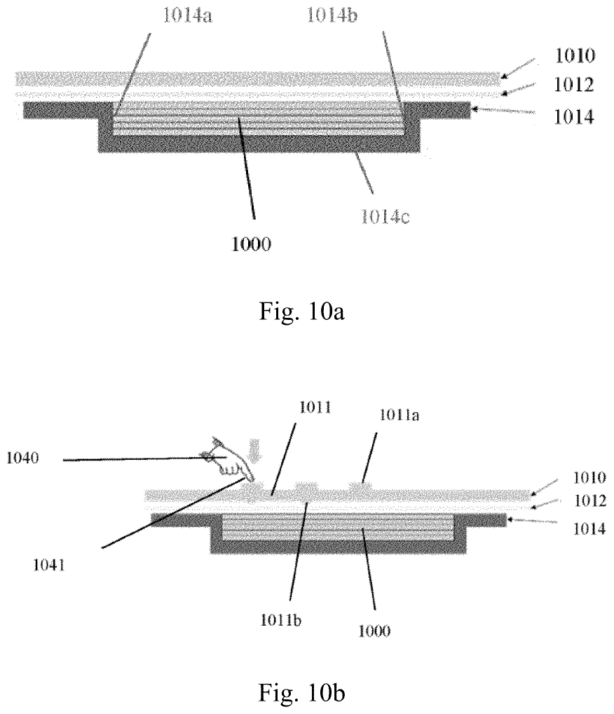

As a result of the insertion of the layer stack 1000 into the cavity, the lower protective layer 1001 rests on the base wall 1014c, whereas the upper protective layer 1005 flushes with the upper edge of the housing 1014, as shown in FIG. 10A or 10B. Both alternatives of FIGS. 10A and 10B further show a glue layer 1012 on top of the upper edge of the housing 1014 and the upper protective layer 1005 to attach a slush skin 1010 providing a HMI.

In the embodiment of FIG. 10B, the HMI includes actuating areas in the form of buttons 1011, which can be pushed by a finger 1041 of the hand 1040 of a user. Said buttons 1011 may each include an upper portion 1011a projecting upwardly and a lower portion 1011b extending downwardly in direction of the layer stack 1000.

Mounting a layer stack under a surface or under a liner in form of the slush skin, in addition to or as alternative to the top protective layer, allows to provide a solid button feeling. The attachment of the surface or under a liner, whether it is with glue or mechanical anchoring, further facilitates serial implementation.

Thus, the production of electroactive polymer transducer devices in larger quantities and high accuracy is possible according to the present disclosure, in particular due to the described manufacturing process of the layer stack. This even allows producing wearable structures on a carrier as intermediate product, which can be inserted into a cavity provided e.g. in the exterior or interior of a vehicle, like a door trim or a dashboard.

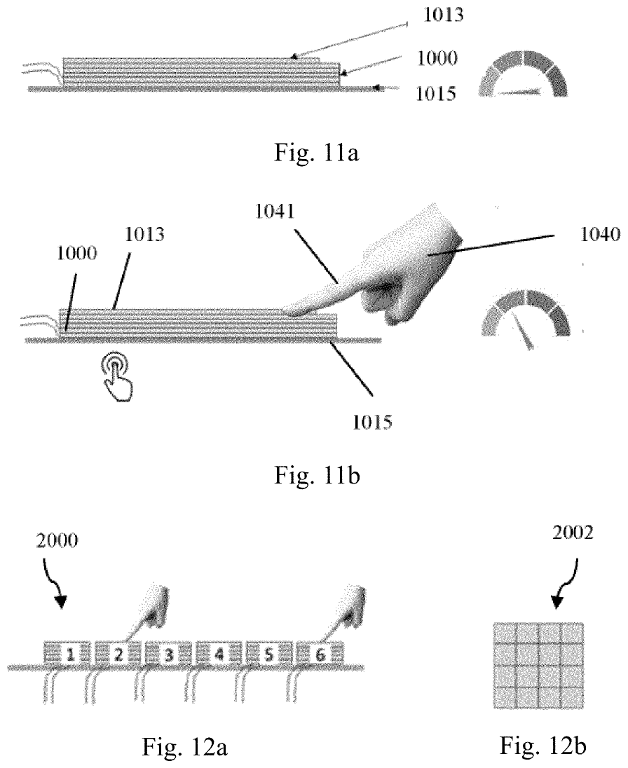

It is to be noted that the layer stack 1000, which is based on the principle of a plane-parallel capacitor, and can provide a dielectric elastomer sensor, can simply include a flexible and stretchable dielectric polymer layer 1003 sandwiched between two compliant electrode layers 1002, 1004, deposited on a textile film 1015 and covered by a decor layer 1013, as shown in FIG. 11A. This structure is beneficial for providing a flexible and sensitive dielectric elastomer tactile sensor, similar to human skin. Such a sensor can be used for measuring mechanical deformations, such as pressure, strain, shear and torsion and can produce vibration or stroke as confirmation of such a deformation, with an example of such a deformation being shown in FIG. 11B.

The sensor of FIGS. 11A and 11B is in particular suited to be used in a method as described with respect to FIG. 7 in order to provide a surface feedback or haptic mechanism. The surface feedback mechanism can be the same haptic mechanism which is used for the confirmation of a HMI function with a localized feedback as provided by a conventional push button.

There is no need for positioning the sensor, in particular the layer stack 1000, on a surface or make it visible, and there is no need for an additional sensor to provide coordinates of a body part on a surface.

With the described sensor, it is possible to provide blind guidance to a body part, especially a finger 1041, to reach a correct location on a surface without having an additional layer providing coordinates or the like. Said correct location is defined by an active area and/or virtual button area described above.

The sensor can detect different signals as pressure, strain, shear and torsion and at the same time can create a movement.

The feedback mechanism to guide said body part only activates after proximity thereof is determined, which results into an optimized system performance. The same function and control mechanism is flexible and applicable to any size of surface without a change of principle method of operation. This provides an optimized solution for different form factors without changing control mechanism.

FIGS. 12A and 12B each show the usage of a layer stack 1000 in a multisensor area. The area of FIG. 12A includes 6 sensors each having a layer stack 1000 as described with respect to FIG. 10A, and the area of FIG. 12B includes 16 sensors, provided by one layer stack 1000 of FIG. 10B. Such sensor areas can be used for example in an internal or external vehicle component as described with respect to FIG. 5 above.

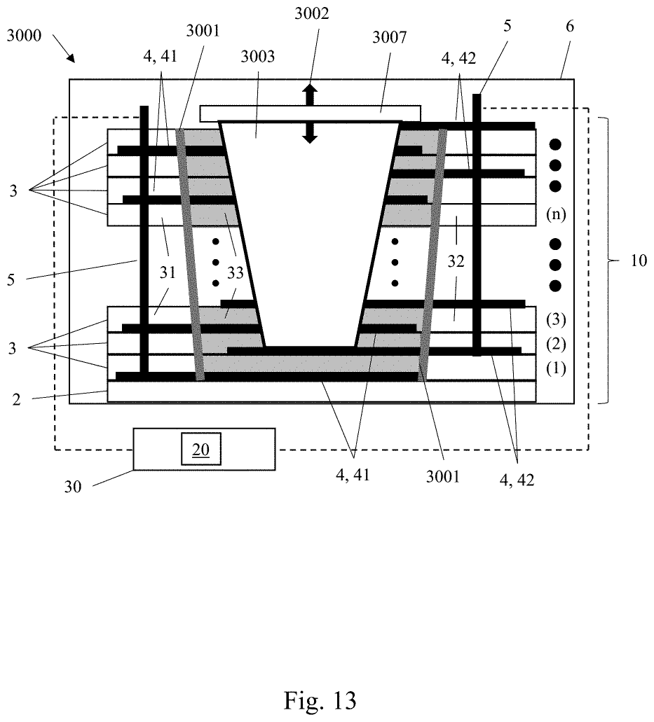

FIG. 13 shows a schematic side view of the layer stack 10 of the electroactive polymer transducer device 3000 that cooperates with the cavity 3003 to form a pump-like system. Here, the cavity 3003 is a truncated cone, but in other variations may take on different forms. The combination of the electroactive polymer transducer device 3000 and the cavity 3003 enables the movement of a fluid, such as, but not limited to, air or water, at a high pressure through the cavity 3003 to facilitate the cleaning of lens, sensors, mirrors or other surfaces on vehicles. Additionally, a cover 3007 seals the cavity 3003 of the electroactive polymer transducer device 3000. The cover may be welded, glued, or fastened to the area surrounding the cavity 3003. The electroactive polymer transducer device 3000 is constructed and functions similar to the electroactive polymer transducer device 1, shown in FIG. 1.

The layer stack 10, is deposited on a base plate 2 via injection technology such as, but not limited to, 3D printing or layer-by-layer injection molding. The layer stack 10 includes an alternating sequence of plastic material layer 3 and electrically conductive layer 4. The plastic material layers 3 may each include an active area 33 (gray shaded areas) made of an elastic polymer providing an electrostrictive effect arranged laterally adjacent beside a first and a second fixation area 31, 32 made of solid plastic material in contact to the active area 33. Between the first and second fixation area 31, 32 and the active area 33 is a transitional zone 3001 where the first and second fixation area 31, 32 and the active area 33 are expected to merge with one another. The electrically conductive layers 4 are arranged in an alternating sequence of first and second electrodes 41, 42 to apply a voltage between first and second electrodes 41, 42 to the active areas 33 in order to induce or sense the electrostrictive effect of the elastic polymer. The first electrode 41 at least partly covers a first fixation area 31 of the fixation area and the active area 33 of the adjacent plastic material layers 3. The second electrode 42 at least partly covers a second fixation area 32 of the fixation area and the active area 33 of the adjacent plastic material layers. The electrically conductive layers 4 are connected through the transitional zone 3001. The first electrodes 41 are connected in parallel to a first polarity of a power supply 20, while the second electrodes 42 are connected in parallel to a second polarity of the power supply 20 by separate conductive pins 5 extending through the stack of layers 10. The left conductive pin 5 extend through the first contacting areas 41 and not the second contacting areas 42 and the right conductive pin 5 extend through the second contacting areas 42 and not the first contacting areas 41. When electricity of the same polarity is applied to the conductive pins 5, the system contracts, and when an opposite polarity is supplied, the system expands. By alternating the polarity supplied to the pins 5 to expand and contract the system, a vertical movement 3002 is created. This encourages fluid to flow through the cavity 3003, thus facilitating the system to act as a pump.

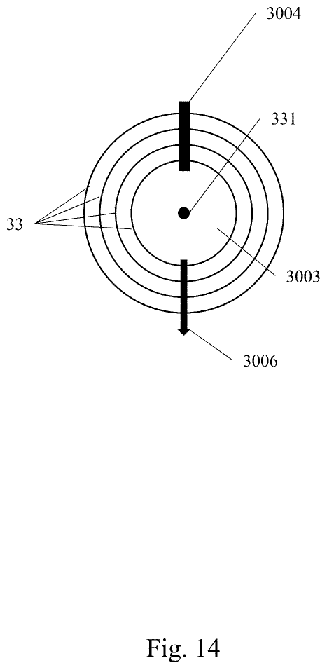

FIG. 14 shows a schematic top view onto the active areas 33 of the plastic material layers 3, as seen in FIG. 13. For a better overview, only the active areas 33 of the plastic material layers 3 are shown. The active areas 33 are arranged symmetrically to the active area 33 underneath, where a center 331 of the active areas 33 coincides for all active areas 33. The active areas 33 have a circular shape and are arranged in a concentric way seen in a vertical direction to a surface of the active areas 33 in this variation, but can take on other shapes or forms in other variations. As seen in FIG. 14, this variation of the system includes an inlet 3004 to facilitate the influx of water or fluid into the system, and a nozzle 3006 to facilitate the egress of the fluid. The inlet 3004 and the nozzle 3006 are in-line with the center 331. In some variations, the inlet 3004 may be located near the top of the cavity 3003 and the nozzle 3006 may be located near the bottom of the cavity 3003. The arrangement of the inlet 3004 near the top of the cavity 3003 ensures that the upwards movement of the electroactive polymer transducer device 3000 corresponds to the inflow of the fluid. The arrangement of the nozzle 3006 near the bottom of the cavity 3003 ensures smooth movement of the fluid. However, the arrangement of the inlet 3004 and nozzle 3006 could be altered in accordance to design requirements.

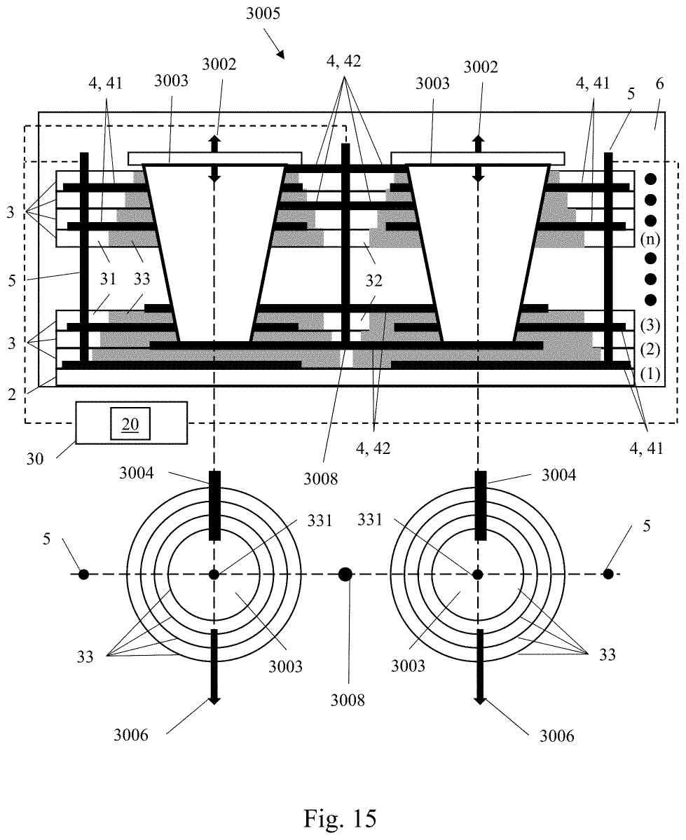

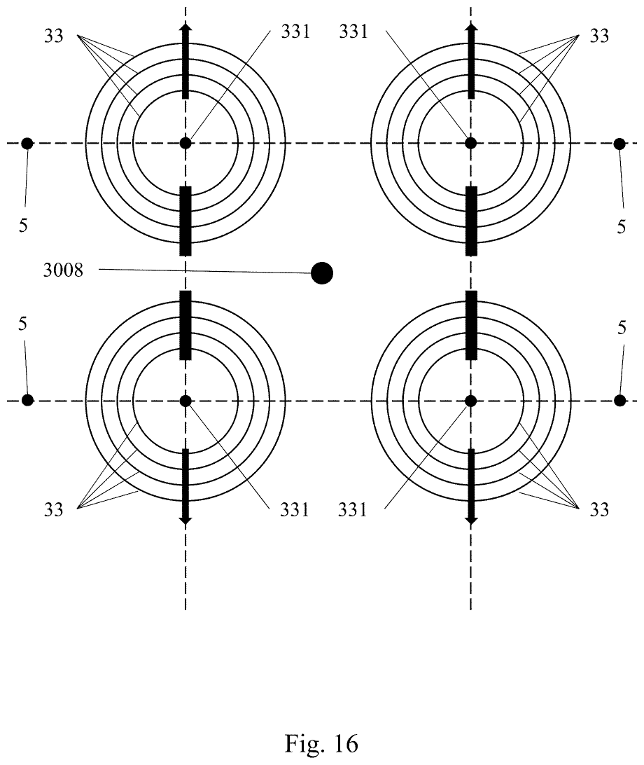

FIG. 15 shows a schematic side view and corresponding top view of a dual electroactive polymer transducer device 3005. The dual electroactive polymer transducer device 3005 includes two electroactive polymer transducer devices 3000, as seen in FIG. 13, that share a joint pin 3008. The dual electroactive polymer transducer device 3005 is constructed similar to the electroactive polymer transducer device 3000, as seen in FIG. 13. The layer stack 10, is deposited on a base plate 2 via injection technology and includes an alternating sequence of plastic material layer 3 and electrically conductive layer 4. The plastic material layers 3 each include an active area 33 arranged laterally adjacent beside a first and a second fixation area 31, 32 in contact to the active area 33. The electrically conductive layers 4 are arranged in an alternating sequence of first and second electrodes 41, 42 to apply a voltage between first and second electrodes 41, 42 to the active areas 33 in order to induce or sense the electrostrictive effect of the elastic polymer. The first electrode 41 at least partly covers a first fixation area 31 of the fixation area and the active area 33 of the adjacent plastic material layers 3. The second electrode 42 at least partly covers a second fixation area 32 of the fixation area and the active area 33 of the adjacent plastic material layers. The first electrodes 41 are connected in parallel to a first polarity of a power supply 20, while the second electrodes 42 are connected in parallel to a second polarity of the power supply 20 by separate conductive pins 5 and the joint pin 3008 respectively extending through the stack of layers 10. The conductive pins 5 extending through the first contacting areas 41 and not the second contacting areas 42. The joint pin 3008 extending through the second contacting areas 42 and not the first contacting areas 41. When electricity of the same polarity is applied to the conductive pins 5 and the joint pin 3008 the system contracts, and when an opposite polarity is supplied the system expands. By alternating the polarity supplied to the pins 5 and joint pin 3008 to expand and contract the system a vertical movement 3002 is created. This encourages the fluid to flow through the cavities 3003, thus facilitating the system to act as a pump.

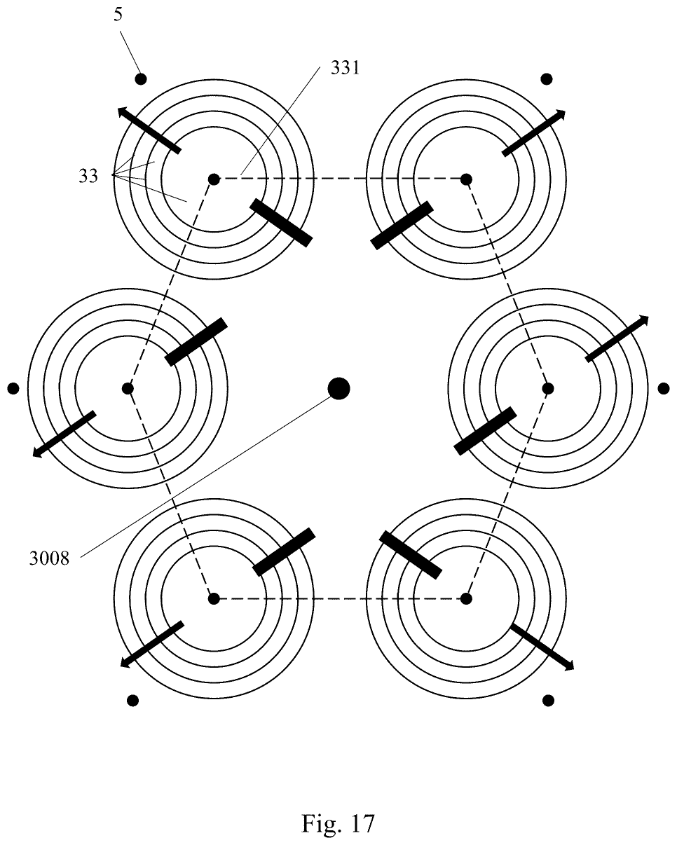

To get a continuous flow of fluid, in one example, at least two electroactive polymer transducer devices 3000 are recommended, with a preferable system design consisting of two to six electroactive polymer transducer devices 3000. As such, each electroactive polymer transducer device 3000 operates sequentially to ensure a continuous flow, but may operate concurrently as well. FIGS. 16 and 17 show a schematic top view of a set of four and six electroactive polymer transducer devices 3000 respectively. The four electroactive polymer transducer device 3000 arrangement is depicted as a square in FIG. 16, and the six electroactive polymer transducer device 3000 arrangement is depicted as a hexagon, depicted by the dashed line, in FIG. 17. As shown in both figures, the electroactive polymer transducer devices 3000 share a joint pin 3008, located in the center of the arrangement. Similarly, the electroactive polymer transducer devices 3000 can be arranged in a series with multiple joint pins 3008 arranged in-between. Each electroactive polymer transducer device 3000 has its own inlet 3004 and nozzle 3006. The configurations of the inlets 3004 and nozzles 3006, as shown in FIGS. 16 and 17, are exemplarily and could be arranged differently in accordance to design requirements. In other variations the electroactive polymer transducer devices 3000 can share a common fluid reservoir and inlet 3004.

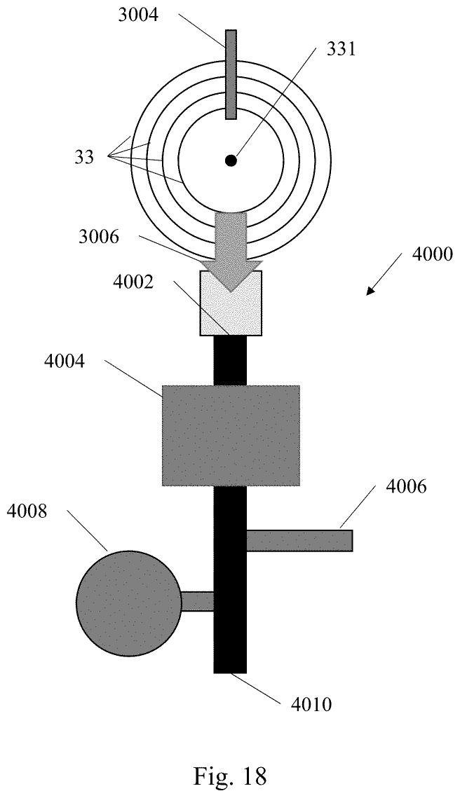

FIG. 18 shows a top schematic view of the electroactive polymer transducer device 3000 in combination with a muffle system 4000. The fluid enters into the electroactive polymer transducer device 3000 via the inlet 3004 where the electroactive polymer transducer device 3000 acts as a pump to provide cyclic bursts having a high peak sound pressure level and frequency. The fluid then exits the electroactive polymer transducer device 3000 into the muffler system 4000 via the nozzle 3006. The muffler system 4000 includes an area change 4002 that facilitates a change in velocity for the fluid. Additionally, the muffler system 4000 includes an expansion chamber 4004 for attenuation of the sound pressure level for wide band frequency. The muffler system 4000 further includes a first resonator 4006 and a second resonator 4008. In this variation the first resonator 4006 is a quarter-wave resonator to provide attenuation of the frequency, and the second resonator 4008 is a Helmholtz resonator to provide well defined sound absorption of the frequency. The muffler system 4000 could use any variation of resonators for the first and second resonator 4006, 4008 to meet design requirements. The muffler system further includes an outlet 4010 to maintain continuous fluid flow to the environment. The muffler system 4000 is intended to reduce noise associated with air systems, but can be configured to accommodate other fluid as well. The muffler system 4000 can also be configured to accommodate multiple electroactive polymer transducer devices 3000.

The features of the present disclosure as disclosed in the foregoing description, in the drawings and in the claims can be essential both individually and in any combination for the implementation of the invention in its various embodiments.

### REFERENCE LIST

1 electroactive polymer transducer device
2 base plate
3 plastic material layers
4 electrically conductive layers
5 conductive pin or via
6 solid top cover
10 stack of layers
20 power supply
30 control unit
31 fixation area, first fixation areas
32 fixation area, second fixation areas
33 active area
41 first electrodes
42 second electrodes
50 vehicle
100 method to produce an electroactive polymer transducer device
110 providing a base plate
120 preparing the stack of multiple layers on top of the base plate
200 method to operate an electroactive polymer transducer device
210 applying a counter-voltage to the electrically conductive layers
220 reversing the applied voltage
331 center of the active area
411 first contacting areas
421 second contacting areas
1000 stack of layers
1001 protective layer
1002 electrode layer
1003 dielectric layer
1004 electrode layer
1005 protective layer
1010 slush skin
1011 button
1011a upper portion
1011b lower portion
1012 glue layer
1013 décor layer
1014 plastic housing
1014a housing side wall
1014b housing side wall
1014c housing base wall
1015 textile film
1020 gap
1030 injection point
1040 hand
1041 finger
2000 vehicle component with multisensor area
2002 vehicle component with multisensor area
3000 Electroactive Polymer Transducer Device
3001 Transition Zone
3002 Pumping Motion
3003 Cavity
3004 Inlet
3005 Dual Electroactive Polymer Transducer Device
3006 Nozzle
3007 Cover
3008 Joint Pin
4000 Muffler System
4002 Area Change
4004 Expansion Chamber
4006 First Resonator
4008 Second Resonator
4010 Outlet

What is claimed is:

1. An electroactive polymer transducer device, comprising:
a housing;
a base film, plate or wall within the housing; and
at least one stack of layers deposited on the base film, plate or wall with at least one housing wall extending from the base film,
wherein the at least one stack of layers comprises an alternating sequence of one or more plastic electroactive material layers and electrically conductive layers on top of each other, with at least one of the one or more plastic electroactive material layers being sandwiched between two of the electrically conductive layers,
wherein each plastic electroactive material layer comprises at least one active area made of an elastic polymer providing an electrostrictive effect, with the active area being arranged laterally adjacent to at least one fixation area or at least one housing wall made of solid plastic material in direct contact to the active area, and the active area extending across the complete plastic material layer,
wherein the electrically conductive layers are arranged in an alternating sequence of a first electrode and a second electrode to apply a voltage between first and second electrodes to each respective active area in order to induce or sense the electrostrictive effect of the elastic polymer of the plastic material layer arranged therebetween,
wherein the at least one stack of layers defines a cavity for a fluid to flow through, and
wherein the at least one stack of layers is prepared by three-dimensional printing technology, layer-by-layer injection molding technology, or pressure casting.

2. The electroactive polymer transducer device of claim 1, wherein the at least one stack of layers comprises at least two stacks of layers connected by a joint pin and deposited on the base film, plate, or wall.

3. The electroactive polymer device of claim 1, further comprising:
an inlet to enable fluid flow into the cavity; and
a nozzle to enable fluid egress from the cavity.

4. The electroactive polymer device of claim 3, further comprising a muffler system located at the outlet of the nozzle.

5. The electroactive polymer transducer device of claim 1, wherein the first electrode at least partly covers a first fixation area of the fixation area and the active area of the adjacent plastic electroactive material layers and the second electrode at least partly covers a second fixation area of the fixation area and the active area of the adjacent plastic electroactive material layers.

6. The electroactive polymer transducer device of claim 1, further comprising a plurality of first electrodes and a plurality of second electrodes,
wherein the one or more plastic electroactive material layers comprise a plurality of plastic electroactive material layers, and the at least one stack of layers comprises ten to fifty sequences of the plurality of plastic electroactive material layer and the electrically conductive layers.

7. The electroactive polymer transducer device of claim 6, wherein the first electrodes are connected in parallel and configured to be connected to a first polarity of a power supply, and the second electrodes are connected in parallel and configured to be connected to a second polarity of the power supply.

8. The electroactive polymer transducer device of claim 7, wherein the first electrodes further comprise first contacting areas at least partly covering the first fixation areas and the second electrodes further comprise second contacting areas at least partly covering the second fixation areas, and
when projected onto the base plate, the first contacting areas at least do not fully cover the second contacting areas, and the second contacting areas at least do not fully cover the first contacting areas.

9. The electroactive polymer transducer device of claim 8, wherein the parallel connection of the first electrodes and the second electrodes is established by at least two separate conductive pins and a joint pin extending through the stack of layers, and
at least two conductive pins extend through the first contacting areas and not the second contacting areas of which the joint pin extends through the second contacting areas and not the first contacting areas.

10. The electroactive polymer transducer device of claim 5, wherein the fixation area comprises separate first and second fixation areas, and
the active area of each plastic material layer is arranged laterally between first and second fixation areas in direct contact with the active area.

11. The electroactive polymer transducer device claim 5, wherein a size of the active areas from layer to layer starts with a biggest size for the plastic electroactive material layer on top of the base plate,
the active areas are arranged symmetrically with the active area underneath, and a center of the active areas coincide for all active areas, and
the active areas have a circular shape and are arranged in a concentric way which is in a vertical direction with respect to a surface of the active areas.

12. The electroactive polymer transducer device of claim 1, wherein the base plate is made of the solid plastic material also used to prepare the fixation areas, and
the base plate is established by one to five separate layers applied on top of each other, or the base film comprises a deformable layer which is a textile film.

13. The electroactive polymer transducer device claim 1, wherein the at least one stack of layers comprises a protective layer on at least one of its two opposite sides, and the at least one stack of layers is covered by a solid top cover, a slush skin, or a décor layer on a side opposite to the base film, plate or wall.

14. The electroactive polymer transducer device of claim 13, wherein the slush skin comprises plastic material and is fixed to the housing, and
one protective layer and a glue layer are interposed, and the slush skin or the décor layer are configured to cover more than the at least one stack of layers to provide a multisensor area.

15. The electroactive polymer transducer device of claim 1, wherein the at least one stack of layers and the base plate or wall are prepared together, and
the base plate or wall and the protective layer or the electrode are arranged next to one another and provided as a combined component.

16. A method of making an electroactive polymer transducer device, comprising:
providing a base film, plate or wall for a stack of multiple layers to be prepared on top of the base film, plate or wall or within a housing with at least one housing wall extending from the base wall;
preparing the stack of multiple layers with at least one plastic material layer, which is sandwiched between two electrically conductive layers and comprising an elastic polymer providing an electrostrictive effect and a dielectric polymer, wherein the stack of multiple layers defines a cavity for fluid to flow through.

17. The method according to claim 16, wherein the stack of multiple layers is provided with a plurality of plastic material layers,
the plastic material layers each comprises an active area made of an elastic polymer providing an electrostrictive effect arranged laterally adjacent to at least one fixation area made of solid plastic material in direct contact to the active area,
the electrically conductive layers are arranged in an alternating sequence of first and second electrodes to apply a voltage between first and second electrodes to the active areas in order to induce or sense the electrostrictive effect of the elastic polymer, and
the first electrode at least partly covers a first fixation area of the fixation area and the active area of the adjacent plastic material layers and the second electrode at least partly covers a second fixation area of the fixation area and the active area of the adjacent plastic material layers.

18. The method according to claim 16, wherein the stack of multiple layers and base plate is prepared by three-dimensional printing technology or by layer-by-layer injection molding technology or casting technology.

19. The method according to claim 16, further comprising attaching the stack of multiple layers to a muffler system.

20. The method according to claim 16, further comprising connecting a first stack of the stack of multiple layers to a second stack of the stack of multiple layers with a joint pin.
